(19) United States
(12) Patent Application Publication
(10) Pub. No.: US 2003/0183954 A1
(43) Pub. Date: Oct. 2, 2003

(54) Magnetic resin composition and method of processing

(76) Inventor: Ronald J. Wolf, Elkhart, IN (US)

Correspondence Address: Ronald J. Wolf, 51082 Stratford Court, Elkhart, IN, 46514, US

(21) Appl. No.: 10/389,468

(22) Filed: Mar. 14, 2003

Related U.S. Application Data
(60) Provisional application No. 60/364,366, filed on Mar. 15, 2002.

(51) Int. Cl. H01L 23/29

(52) U.S. Cl. 257/795

(57) ABSTRACT

A resin magnetic material composition including a resin and a non-ceramic magnetic filler.

### CROSS-REFERENCE TO RELATED APPLICATIONS

This is a non-provisional patent application based upon U.S. Provisional Patent application, Serial No. 60/364,366 bearing the title “Magnetic Resin Composition and Method of Processing.” filed on Mar. 15, 2002.

### BACKGROUND OF THE INVENTION

1. Field of the Invention

The present invention relates to a method and apparatus of forming a magnetic material and, more particularly, to a method and apparatus for the forming of a non-ceramic magnetic material.

2. Description of the Related Art

Resin based systems are used in connection with devices having magnetic or electronic characteristics. Often the resin serves as a packaging or a support structure to which other devices may be attached.

Epoxy is one form of a resin based system, which is often used to encapsulate a semiconductor device. Epoxies are chosen because they have a nonconductive characteristic as well as desirable moisture resistance and an ability to adhere to the semiconductor device. As such, epoxy resins are used for the packaging of integrated circuits and discrete components.

Epoxy resin is combined with a hardener and a filler in many electronic applications. Fillers are added to the epoxy-hardener combination to alter such things as the thermal conductivity or coefficient of expansion of the resulting combination. Often such things as silica, quartz, calcium silicate, fiberglass, earth clays, alumina, and other similar or combinations thereof are added.

Another type of filler that has been used in this type of assembly includes ceramic compositions having magnetic properties, such as those disclosed in U.S. Pat. No. 6,274,939 and U.S. Pat. No. 6,414,398. In these two patents, ceramic fillers, which include strontium ferrite, barium ferrite and mixtures thereof are included with the epoxy resin and are formed around a semiconductor device. A problem with these compositions is that they are not able to take advantage of the magnetic properties of electrically-conductive magnetic fillers. An additional problem is that ceramic magnetic materials demonstrate a relatively large reversible temperature coefficient of induction loss of over −0.19%/° C. This constitutes a 19% loss of magnetic field strength in the temperature range of from 25° C. to 125° C.

What is needed in the art is the ability to use high magnetic field strength particles.

### SUMMARY OF THE INVENTION

The present invention relates to a material composition including a resin and a non-ceramic magnetic material.

The invention comprises, in one form thereof, a resin magnetic material composition including a resin and a non-ceramic magnetic filler.

The invention comprises, in another form thereof, a semiconductor assembly including a semiconductor device, a resin and an amount of surface insulated magnetic material at least partially combined with the resin and in at least partial contact with the semiconductor device.

In yet another form thereof, the present invention relates to a method of forming a shaped magnet including the steps of providing a plurality of magnetic particles, electrically insulating at least a portion of the surface of each of the plurality of magnetic particles and mixing the plurality of magnetic particles with a resin thereby forming a resin magnetic material composition.

An advantage of the present invention is that the magnetic material particles are of a very temperature stable material, such as alnico, neodymium or samarium. Further, neodymium or samarium have a very high magnetic energy level.

Another advantage of the present invention is that electrically conductive magnetic materials are used proximate to a semiconductor device.

Yet another advantage of the present invention is that the magnetic material may have multiple poles of magnetism geometrically arranged therein.

And yet still another advantage of the present invention is that the material composition can be formed at low pressures and little or no temperature elevation to form the intended device.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 is a top view of an encapsulated semiconductor device placed into a magnetic cup embodying the present invention;

FIG. 2 is a cross-sectional view taken along plane 2-2 of the encapsulated semiconductor device of FIG. 1;

FIG. 3 is a cross-sectional view of the encapsulated semiconductor device of FIGS. 1 and 2 along plane 3-3 of FIG. 1;

FIG. 4 is a top view of an encapsulated semiconductor device proximate to a metal shunt in a magnetic cup of the present invention;

FIG. 5 is a side, cross-sectional view taken along plane 5-5 of FIG. 4;

FIG. 6 is the semiconductor device of FIGS. 4 and 5 shown in cross-section, taken along plane 6-6 of FIG. 4;

FIG. 7 is a top view of a semiconductor die encapsulated in the magnetic cup of the present invention;

FIG. 8 is a partially cross-sectional view taken along plane 8-8 of FIG. 7; and

FIG. 9 is a partially cross-sectional view of the devices of FIGS. 7 and 8 taken along plane 9-9 of FIG. 7.

Corresponding reference characters indicate corresponding parts throughout the several views. The exemplifications set out herein illustrate preferred embodiments of the invention, and such exemplifications are not to be construed as limiting the scope of the invention in any manner.

### DETAILED DESCRIPTION OF THE PRESENT INVENTION

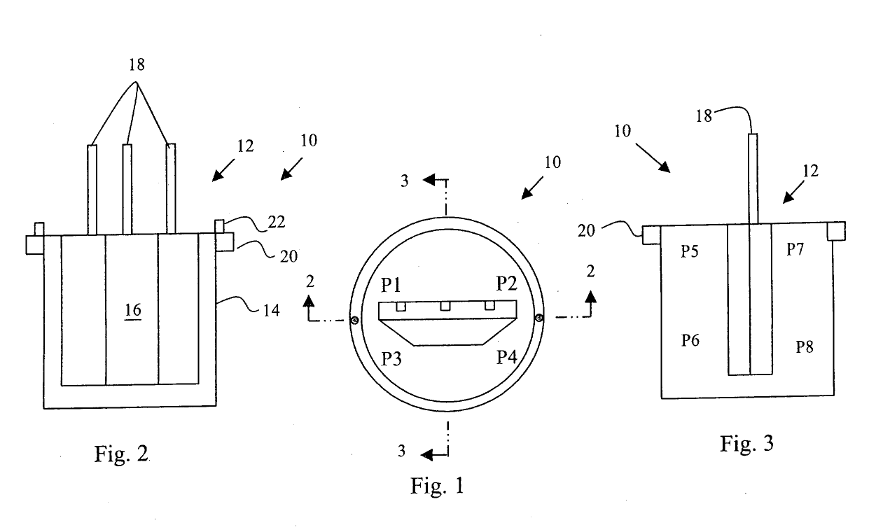

Referring now to the drawings, and particularly to FIGS. 1-3, there is shown a magnetic cup assembly 10 embodying the present invention, including encapsulated semiconductor device 12 and magnetic cup 14. Encapsulated semiconductor device 12 includes encapsulant 16 surrounding a semiconductor die (not shown), and device leads 18, which are electrically connected to an internal semiconductor device. Magnetic cup 14 includes ring 20 and orientating protrusions 22. Ring 20 may be made of a metal or other compound or part of the material of magnetic cup 14. Ring 20 allows for the physical mounting of magnetic resin cup assembly 10 to a fixture, not shown. Orientating protrusions 22 may be oriented around ring 20 or even on a top portion of magnetic cup 14 to provide orientation for purposes of mounting magnetic resin cup assembly 10.

The present invention provides for a low-pressure bonded molding process to form magnetic cup 14. Magnetic cup 14 may be formed without encapsulated semiconductor device 12 enclosed therein, as in the form of an empty cup. An electrical device may be inserted at a later point in an assembly process.

The material composition of magnetic cup 14 includes a resin, a hardener, and magnetic material of various particle sizes. The magnetic material is electrically-conductive such as alnico, samarium or neodymium, or a combination thereof. Particles of the magnetic material are mixed with a resin such as an epoxy, urethane, polyester or silicone or a combination thereof. The composition can be processed in the form of various consistencies, such as liquid, paste, or powder.

As an example, magnetic cup 14 may be molded using a samarium magnetic material mixed with a thermosetting polyester resin composition composed of an unsaturated polyester resin, an unsaturated monomer capable of cross-linking the unsaturated polyester resin, an internal mold release, and a free radical initiating agent to polymerize the composition after it has been injected into a heated mold. In addition, low-shrink additives, adhesion promoters, wetting agents, reinforcing fillers, pigments, and other property-specific enhancing additives may be used in the mix.

The present invention advantageously allows for lower amounts of magnetic filler to be added than in the prior art to produce similar magnetic characteristics. In addition, the present invention utilizes very low molding pressure, which allows cost-effective, low-volume molding processes to be used. Additionally, the process produces magnets that operate at elevated temperature ranges, which is difficult for compression or other injected molding techniques.

Unsaturated polyester resins can be chosen from commercially-available polyesters such as those made from organic acids and dihydric alcohols, and vinyl esters. The common monomers used for cross-linking are stylene, vinyl tolulene, and diallylphthallate. Internal mold release agents include aliphatic, organic salt, or amides such as zinc stearate or bisstearamides. Free radical initiators include organic peroxides such as dicumylperoxide or t-amylperbenzoate.

Alternatively, resins can be mixed with magnetic materials such as thermosetting epoxy resin compositions. Epoxy resin compositions include an epoxy resin, a curing agent capable of cross-linking the epoxy, an internal mold release and an accelerator to increase the reaction rate of the polymerization. The same type of additives as used in the polyester molding compounds can be used in the epoxy molding compounds.

Epoxy resins include those that are derived from bisphenol A, bisphenol F, bisphenol A novolak, diaminodiphenyl methane, and alicyclic adipates. Curing agents include phenyl resins, carbolic acids or acids and hydrides, polymines, polymides, polysulfides and other acid complexes. Internal mold release agents include aliphatic, organic salts or amides such as zinc stearate or bisstearamides. Accelerators that are utilized in the present invention include amines, amine salts, heterocycline nitrogen compounds, and phosphonium, sulfonium, and arsonium compounds.

Alternate resins, which may be mixed to form magnetic cup 14 include silicon or urethane-based compositions, which additionally allows the production of flexible items such as a magnetic diaphragm utilized for such applications as vacuum or pressure sensors.

A mixed compound of one of the above-described compositions is mixed with a magnetic material. The mixed compound is then molded by using an injection or transfer molding press. With low pressure, such as 500 pounds per square inch and even as low as 200 to 250 pounds, the thermosetting compound and magnetic material mix is injected into mold cavities and heated to approximately 140° C. to 165° C. In approximately 60 to 90 seconds, the thermosetting compound and magnetic material mix solidify into the desired shape. The temperatures and times may vary depending upon the material composition utilized. Since the molding pressure is so low, a magnetic orientation field can be added into the mold cavities. The orientation field may be provided by electrically-generated fields or by permanent magnets placed within the mold cavities. The polarity of the magnetic material in magnetic cup 14 is illustrated in FIGS. 1 and 3 by the using of P1 through P8. P1 through P8 each illustrate a potential pole orientation of the magnetic cup 14. For example, P1 and P4 may be the north pole of a magnet while P2 and P3 are a south pole. In a like manner, P5 and P6 may represent a north pole and P7 and P8 a south pole, or any combination thereof. The orientating field of the magnets surrounding a mold cavity during the molding process orient the magnetic material such as samarium, neodymium, or alnico.

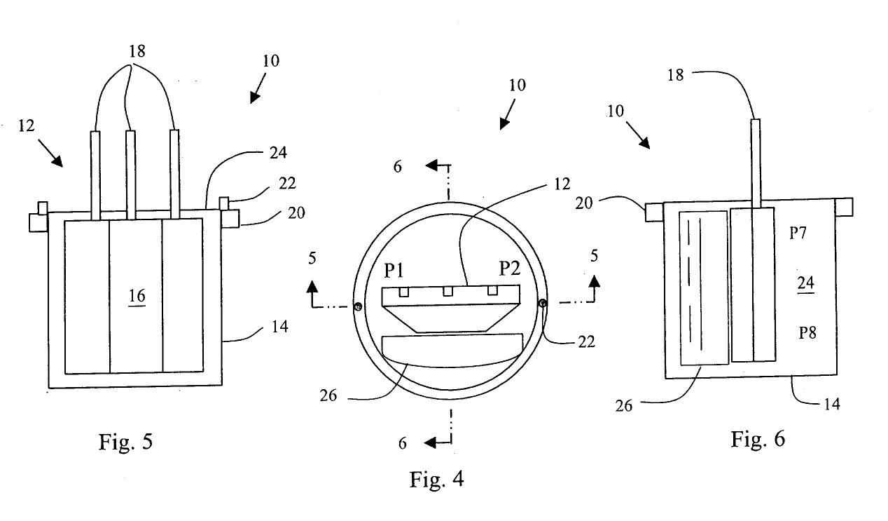

Now, additionally referring to FIGS. 4-6, there is shown a fully-encapsulated semiconductor device 12 within magnetic surrounding material 24 that fully encloses encapsulated semiconductor device 12. Semiconductor device 12 includes devices sensitive to magnetic fields and able to detect magnetic fields, such as a Hall effect device 12. Whereas leads 18 are now in direct contact with magnetic cup 14, the utilization of otherwise electrically-conductive magnetic particles have been electrically insulated on their surface prior to mixing with the epoxy resin. A surface insulated magnetic filler includes magnetic particles that are otherwise electrically conductive, having an insulating layer formed thereon to provide a substantially non-electrically conducting surface on each of the magnetic particles. The surface insulated magnetic particles may contain a substantial insulation layer that is not entirely impervious to electrical contact. However, a substantial portion of the surface of each magnetic particle is covered with electrical insulation such that the probability of electrical conduction over even a short range is substantially eliminated.

FIGS. 4 and 6 illustrate the positioning of a ferrous shunt 26 proximate to encapsulated semiconductor device 12. Ferrous shunt 26 is used to direct and orient magnetic flux produced in magnetic cup 14 and other magnetic fields conducted thereto.

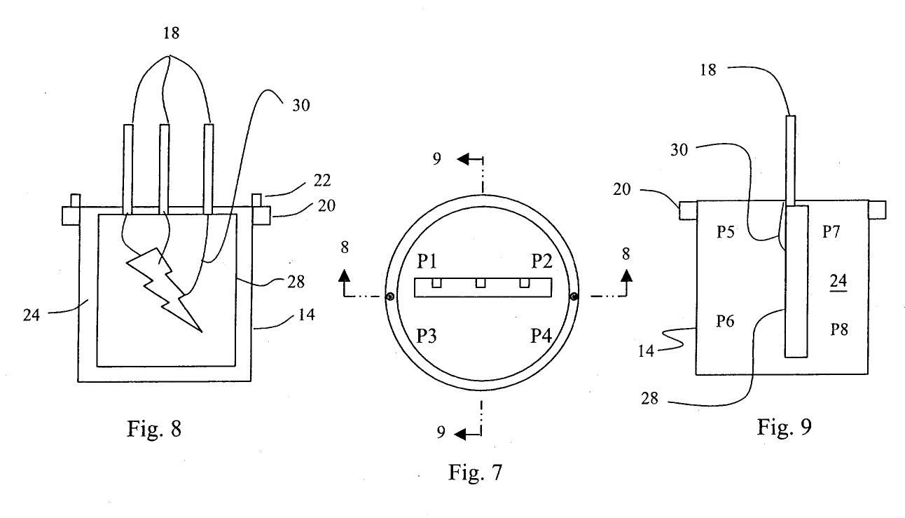

Now, additionally referring to FIGS. 7-9, there is shown a semiconductor die 28 and interconnecting leads 30. In this embodiment of the present invention, an unencapsulated semiconductor die 28 is positioned within the surrounding magnetic material 24 of the device. Advantageously, the use of surface insulated magnetic material as a filler advantageously allows the strong magnetic field of a samarium or neodymium magnetic material to be proximate to magnetically-influenced components related to semiconductor die 28. As in all of the prior embodiments, the polarities that can be induced in magnetic material 24 may consist of several geometries, including radially orienting the magnetic field or by orienting poles at various positions within magnetic material 24.

Advantageously, the orientating of a magnetic field about semiconductor die 28 and/or encapsulated semiconductor device 12 allows for a magnetic biasing of the semiconductor devices. Such magnetic biasing may enhance the ability of the semiconductor devices to detect ferrous or other magnetic materials proximate to magnetic resin assembly 10.

The magnetic materials described herein have a particle size that often exceeds 1.5 microns and may be entirely composed of materials that exceed 2.0 microns.

The insulation over an electrically-conductive magnetic material allows the use of these stronger magnetic strength materials than was previously available. The use of these materials allow the inherent advantageous properties of these materials to be used in an environment where electrical conductivity would be undesirable. Surface insulated electrically-conducting materials described herein have a lower reversible magnetic strength temperature loss than previous materials, such as ceramic magnetic materials. Further, the difference in the percentage change in reversible magnetic strength per degree Celsius is significant between ceramic and non-ceramic magnetic materials. For example, most ceramic magnetic materials display a −0.19% per degree Celsius reversible temperature coefficient of induction loss whereas samarium, which is an electrically-conductive magnetic material, displays only a −0.035% per degree Celsius reversible temperature coefficient of induction loss. The present invention uses material that demonstrates less than −0.13%/° C. reversible temperature coefficient of induction loss. And, preferably material that demonstrates less than −0.08%/° C. reversible temperature coefficient of induction loss is used. This advantageously allows less magnetic material to be used to provide a certain magnetic field over a temperature range rather than a ceramic-type material. Further, more magnetic energy closer to a particular part or point is possible than with ceramic magnetic materials.

The present invention advantageously allows an anisotropic result in magnetic material due to the ability to locate orientation coils or magnetic fields close to the injected material. Nonetheless, an isotropic result can also be designed and utilized. Advantageously, the present invention is capable of producing a magnetic field of at least 1 gauss and even higher magnetic fields of over 500 gauss in a magnetic cup 14.

While this invention has been described with respect to preferred embodiments, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A resin magnetic material composition, comprising:
a resin; and
a non-ceramic magnetic filler.

2. The material composition of claim 1, wherein said non-ceramic magnetic filler is comprised of:
a plurality of electrically conductive magnetic particles; and
an insulating layer on each of said plurality of electrically conductive magnetic particles, such that said magnetic filler is not electrically conductive.

3. The material composition of claim 2, wherein the resin magnetic material composition is placed under pressure into a mold having a geometric shape.

4. The material composition of claim 3, wherein said pressure is less than approximately 500 pounds per square inch.

5. The material composition of claim 2, wherein said plurality of magnetic particles consist of at least one of alnico, samarium and neodymium.

6. The material composition of claim 1, wherein said non-ceramic magnetic filler includes a plurality of magnetic particles having less than −0.13%/° C. reversible temperature coefficient of induction loss.

7. The material composition of claim 6, wherein said plurality of magnetic particles have less than −0.08%/° C. reversible temperature coefficient of induction loss.

8. A semiconductor assembly, comprising:
a semiconductor device;
a resin; and
an amount of surface insulated magnetic filler at least partially combined with said resin and in at least partial contact with said semiconductor device.

9. The device of claim 8, further comprising a hardener combined with said resin.

10. The device of claim 8, wherein said surface insulated magnetic filler is comprised of:
a plurality of electrically conductive magnetic particles; and
a insulating layer on each of said plurality of electrically conductive magnetic particles, such that said magnetic filler is not electrically conductive.

11. The device of claim 10, wherein the material combination is placed under pressure into a mold having a geometric shape.

12. The device of claim 11, wherein said pressure is less than approximately 500 pounds per square inch.

13. The device of claim 10, wherein said plurality of magnetic particles consist of at least one of alnico, samarium and neodymium.

14. The device of claim 10, further comprising a ferrous shunt proximate to said semiconductor device.

15. The device of claim 10, wherein said plurality of magnetic particles have less than −0.08%/° C. reversible temperature coefficient of induction loss.

16. A method of forming a shaped magnet, comprising the steps of:
providing a plurality of magnetic particles;
electrically insulating at least a portion of the surface of each of said plurality of magnetic particles; and
mixing said plurality of magnetic particles with a resin thereby forming a resin magnetic material composition.

17. The method of claim 16, wherein said magnetic particles are non-ceramic electrically conductive magnetic particles.

18. The method of claim 17, further comprising the step of transferring said resin magnetic material composition into a mold under pressure.

19. The method of claim 18, wherein said pressure is less than approximately 500 pounds per square inch.

20. The method of claim 19, wherein said pressure is less than approximately 250 pounds per square inch.
